(19) United States
(12) Patent Application Publication
(10) Pub. No.: US 2013/0120983 A1
(43) Pub. Date: May 16, 2013

(54) LED LAMP STRUCTURE AND METHOD OF INCREASING LIGHT RADIATION ANGLE OF SAME

(71) Applicant: Bor-Bin TSAI, New Taipei City (TW)

(72) Inventor: Bor-Bin TSAI, New Taipei City (TW)

(21) Appl. No.: 13/296,454

(22) Filed: Nov. 15, 2011

(51) Int. Cl. F21V 1/00; H05K 13/00; F21V 29/00

(52) U.S. Cl. 362/235; 29/592.1

(57) ABSTRACT

A light-emitting-diode (LED) lamp structure includes a lamp holder having a top opening, an LED module mounted to the top opening of the lamp holder and including at least one LED chip and a circuit board, and a lampshade assembled to a top of the lamp holder to enclose the LED module therein. The lampshade has an inner wall surface coated with at least one half-mirror layer, so that part of the light emitted from the LED module onto the half-mirror layer is reflected toward two lateral sides and a rear side of the lamp holder, enabling the LED lamp structure to have an increased light radiation angle and illuminate a wider area. A method of increasing light radiation angle and illuminating area of LED lamp structure is also disclosed.

### FIELD OF THE INVENTION

The present invention relates to a light-emitting-diode (LED) lamp structure, and more particularly to an LED lamp structure that has increased light radiation angle and illuminates a wider area. The present invention also relates to a method of increasing the light radiation angle of an LED lamp structure.

### BACKGROUND OF THE INVENTION

Due to the constant progress in various technological fields, the conventional bulbs has been gradually replaced by light-emitting diode (LED), which has become known among the general public now. The LED has the advantages of small volume, low power consumption, high lighting efficiency, long service life, and non-mercury pollution, and is therefore widely adopted by optoelectronic industry and illumination industry to serve as an LED light source, which has been widely present in people's daily life.

FIG. 1 shows a conventional lamp using LED as a light source thereof. As shown, the conventional LED lamp includes a lampshade 10, a lamp holder 11, and an LED module 12. The lamp holder 11 has a top opening 111, to which the LED module 12 is fixedly mounted. The LED module 12 includes at least one LED chip 121 and a circuit board 122. The lampshade 10 is connected to a top of the lamp holder 11 to enclose the LED module 12 therein.

The light emitted from the LED module 12 is directional and has a radiation angle about 120°. Therefore, the LED module 12 provides highly intense forward light but relatively weak or even no lateral and rear light. That is, the conventional LED lamp fails to illuminate areas at lateral and rear sides thereof and therefore forms relatively darker areas around the LED light source.

In brief, the conventional LED lamp has the following disadvantages: (1) having a relatively narrow light radiation angle; and (2) illuminating a relatively small area.

It is therefore tried by the inventor to develop an improved LED lamp structure and a method of increasing the light radiating angle and illuminating area of an LED lamp structure, so as to overcome the problems in the conventional LED lamp.

### SUMMARY OF THE INVENTION

A primary object of the present invention is to provide an LED lamp structure that has increased light radiation angle and illuminates a wider area.

Another object of the present invention is to provide a method for increasing light radiating angle and illuminating area of an LED lamp structure.

To achieve the above and other objects, the LED lamp structure according to the present invention includes a lamp holder, an LED module, and a lampshade. The lamp holder has a top opening, to which the LED module is mounted. The LED module includes at least one LED chip and a circuit board. The lampshade is assembled to a top of the lamp holder to enclose the LED module therein, and is coated on part of or the whole of an inner wall surface thereof with at least one half-mirror layer.

To achieve the above and other objects, the method of increasing the light radiation angle of an LED lamp structure according to the present invention includes the following steps:

providing a lamp holder and mounting an LED module on the lamp holder for emitting light;

providing a lampshade and coating a half-mirror layer on an inner wall surface of the lampshade; and

assembling the lampshade to a top of the lamp holder to enclose the LED module therein, so that part of the light emitted from the LED module onto the half-mirror layer of the lampshade passes through the lampshade while other part of the light is reflected by the half-mirror layer to thereby enable an increased light radiation angle.

With the above-described LED lamp structure and the method of increasing the light radiation angle of the LED lamp structure, part of the light emitted from the LED module onto the lampshade will pass through the lampshade while other part of the light is reflected by the half-mirror layer toward two lateral side and a rear side of the lamp holder. Thus, the LED lamp structure has an increased light radiation angle to illuminate a wider area.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an assembled perspective view of a conventional LED lamp;

FIG. 2A is an exploded perspective view of an LED lamp structure according to a first embodiment of the present invention;

FIG. 2B is an assembled view of FIG. 2A;

FIG. 2C is a vertical sectional view of FIG. 2B;

FIG. 3 is a vertical sectional view of an LED lamp structure according to a second embodiment of the present invention;

FIG. 4 is an assembled perspective view of an LED lamp structure according to a third embodiment of the present invention;

FIG. 5A is an exploded perspective view of an LED lamp structure according to a fourth embodiment of the present invention;

FIG. 5B is an assembled view of FIG. 5A; and

FIG. 6 is a flowchart showing the steps included in a method according to the present invention for increasing the light radiation angle and the illuminating area of an LED lamp structure.

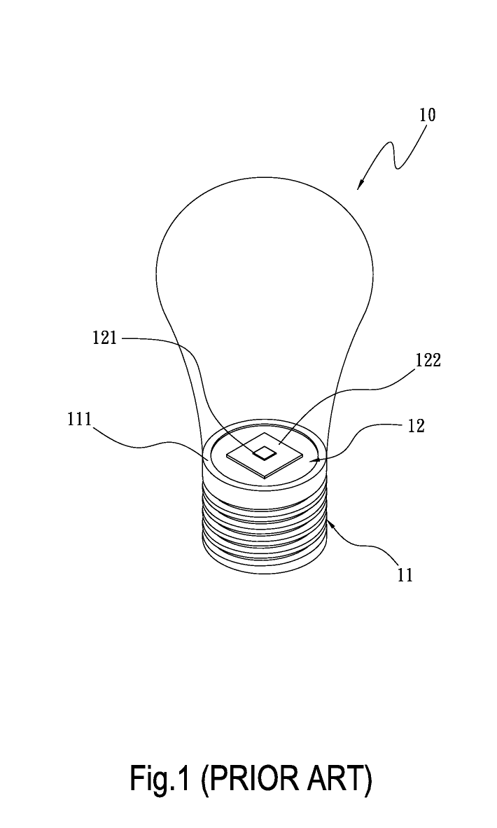

### DETAILED DESCRIPTION OF THE PREFERRED EMBODIMENTS

The present invention will now be described with some preferred embodiments thereof and with reference to the accompanying drawings. For the purpose of easy to understand, elements that are the same in the preferred embodiments are denoted by the same reference numerals.

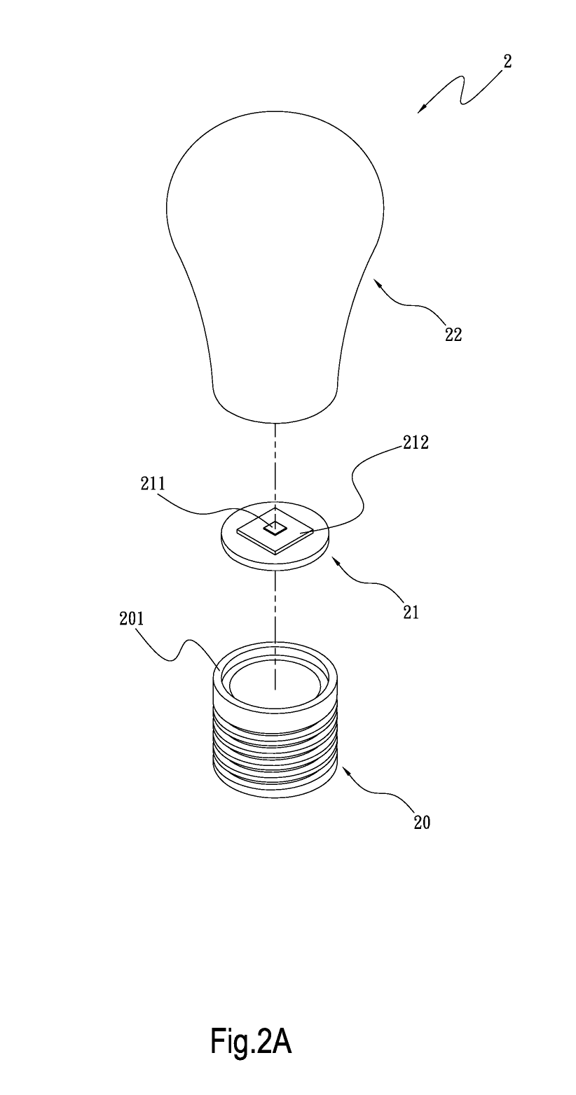

Please refer to FIGS. 2A and 2B that are exploded and assembled perspective views, respectively, of an LED lamp structure 2 according to a first embodiment of the present invention, and to FIG. 2C that is a vertical sectional view of FIG. 2B. As shown, in the first embodiment, the LED lamp structure 2 includes a lamp holder 20 having a top opening 201; an LED module 21 mounted to the top opening 201 of the lamp holder 20 and having at least one LED chip 211 and a circuit board 212; and a lampshade 22 connected to a top of the lamp holder 20 to enclose the LED module 21 therein. The lampshade 22 is coated on at least part of an inner wall surface with at least one half-mirror layer 221.

The half-mirror layer 221 may be a silver coating, an aluminum coating, or any other reflective coatings.

When the LED module 21 emits light onto the lampshade 22 coated with the half-mirror layer 221, a part of the light will pass through the lampshade 22 while other part of the light is reflected by the half-mirror layer 221 toward two lateral sides and a rear side of the lamp holder 20. Therefore, the light emitted from the LED chip 211 may have an increased radiation angle to illuminate a wider area.

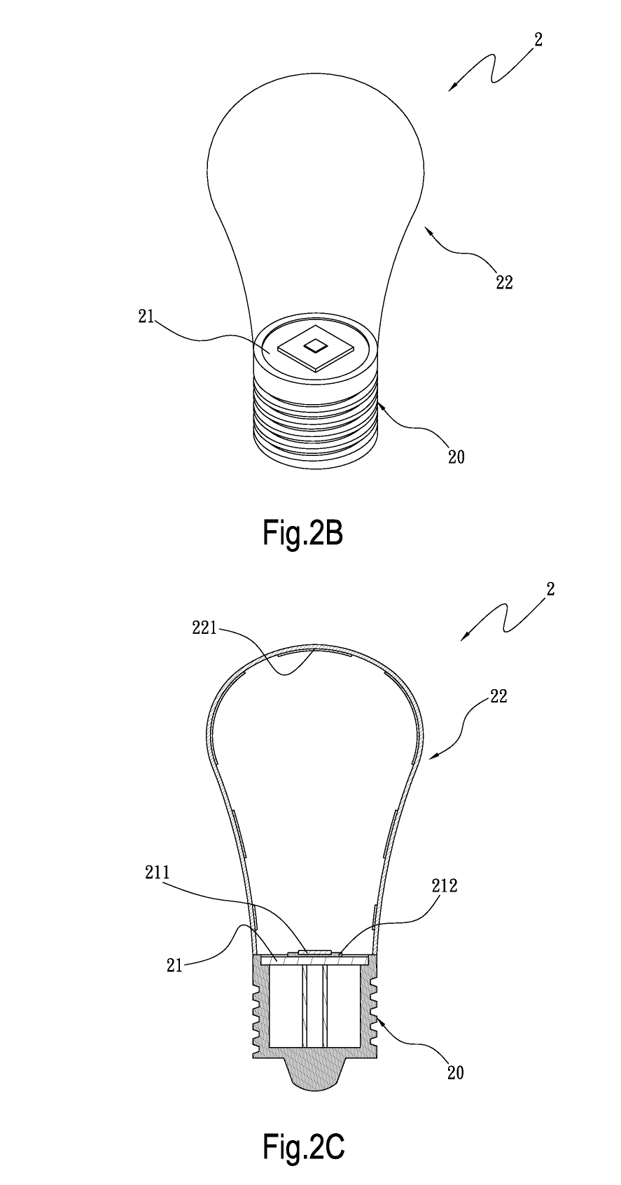

FIG. 3 is a vertical sectional view of an LED lamp structure 2 according to a second embodiment of the present invention. As shown, the LED lamp structure 2 in the second embodiment is generally structurally similar to the first embodiment, except that the half-mirror layer 221 is coated over the whole inner wall surface of the lampshade 22. Similarly, when the LED module 21 emits light onto the half-mirror layer 221, a part of the light passes through the lampshade 22 while other part of the light is reflected by the half-mirror layer 221 toward two lateral sides and a rear side of the lamp holder 20. Therefore, the light emitted from the LED chip 211 may have an increased radiation angle to illuminate a wider area.

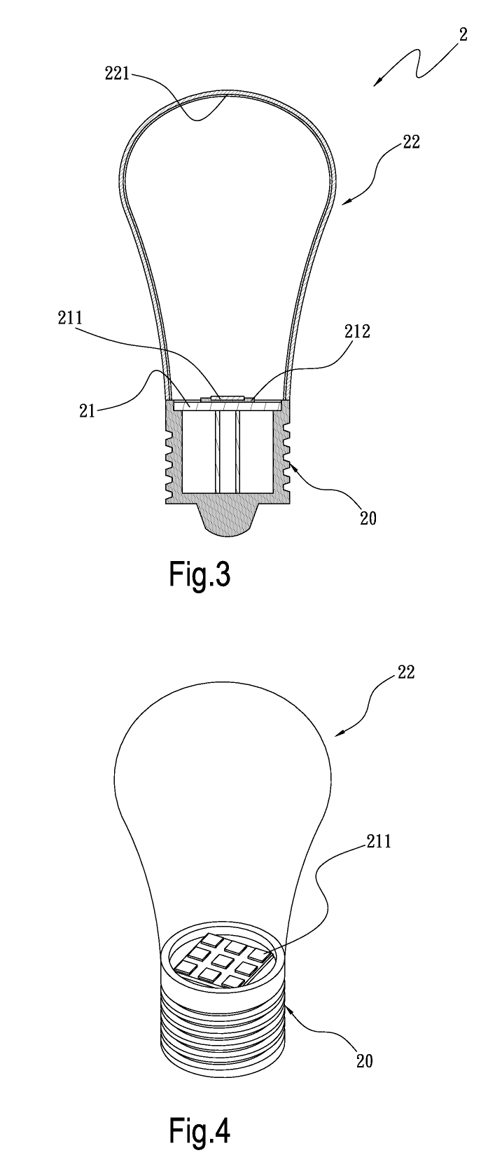

The LED lamp structure 2 according to the present invention may be differently designed according to different user requirements. For example, in an LED lamp structure 2 according to a third embodiment of the present invention as shown in FIG. 4, the LED module 21 may include more than one LED chip 211, and the number of the LED chips 211 may be increased or decreased according to a user's actual need for brightness.

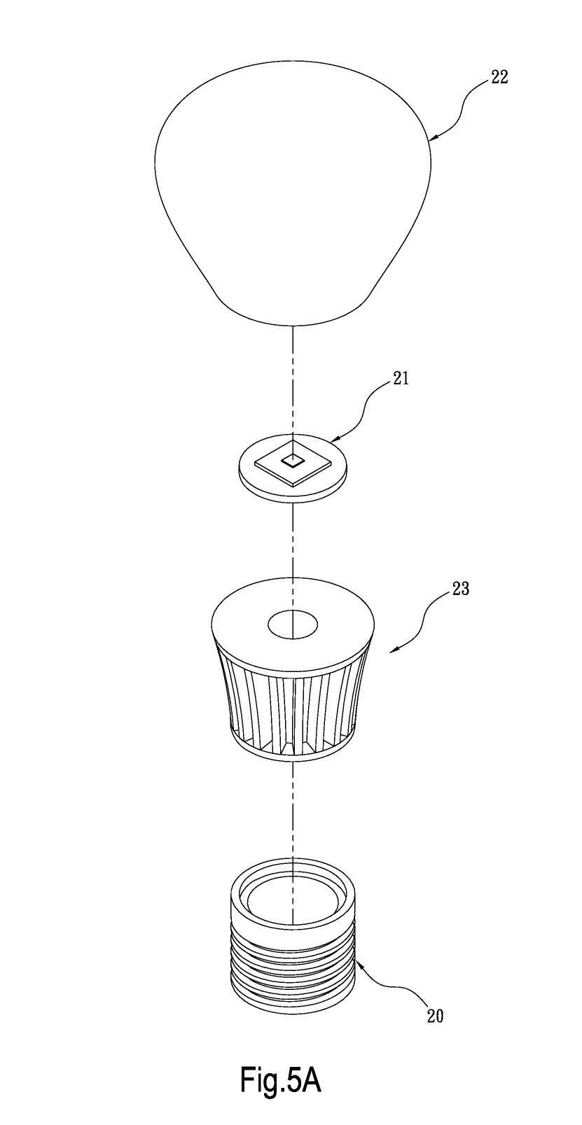

Please refer to FIGS. 5A and 5B that are exploded and assembled perspective views, respectively, of an LED lamp structure according to a fourth embodiment of the present invention. As shown, the LED lamp structure in the fourth embodiment is generally structurally similar to the previous embodiments, except for a plurality of radiating fins 23 that are provided between the LED module 21 and the lamp holder 20. Heat generated by the LED module 21 during the operation thereof can be radiated from the radiating fins 23 into external environment to thereby achieve the purpose of heat dissipation and accordingly, prolonged service life of the LED module 21.

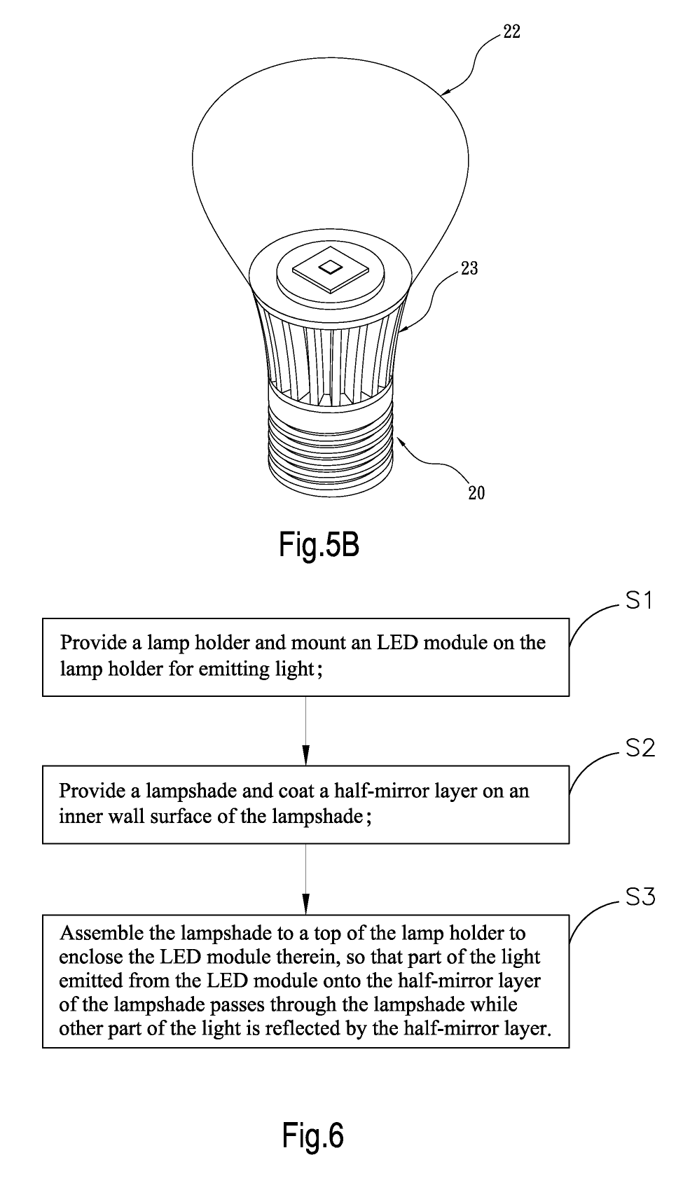

The present invention also provides a method of increasing the light radiation angle and illuminating area of the above-described LED lamp structure. FIG. 6 is a flowchart showing steps Si to S3 included in the method of the present invention. Please refer to FIG. 6 along with FIG. 2C.

In the step S1, a lamp holder 20 is provided and an LED module 21 is mounted thereon.

More specifically, a lamp holder 20 is provided and an LED module 21 is mounted thereon. The LED module 21 includes at least one LED chip 211 and a circuit board 212.

In the step S2, a lampshade 22 is provided and a half-mirror layer 221 is coated on an inner wall surface of the lampshade 22.

More specifically, a lampshade 22 is provided and a half-mirror layer 221 is coated on an inner wall surface of the lampshade 22. The half-mirror layer 221 can be a silver coating, an aluminum coating, or any other reflective coatings.

In the step S3, the lampshade 22 is assembled to a top of the lamp holder 20 to enclose the LED module 21 therein, so that when the LED module 21 emits light onto the half-mirror layer 221, a part of the light passes through the lampshade 22 while other part of the light is reflected to thereby enable an increased radiation angle of light.

More specifically, the lampshade 22 is assembled to a top of the lamp holder 20 to enclose the LED module 21 therein, so that when the LED module 21 emits light onto the half-mirror layer 221, a part of the light passes through the lampshade 22 while other part of the light is reflected by the half-mirror layer 221 toward two lateral sides and a rear side of the lamp holder 20.

The half-mirror layer 221 can be coated on part of or the whole of the inner wall surface of the lampshade 22.

With the above-described method, part of the light emitted from the LED module 21 onto the lampshade 22 internally coated with the half-mirror layer 221 will pass through the lampshade 22 while other part of the light is reflected by the half-mirror layer 221 toward two lateral side and a rear side of the lamp holder 20. Thus, the light emitted from the LED chip 211 has an increased radiation angle to illuminate a wider area.

In brief, the LED lamp structure according to the present invention has the following advantages: (1) having increased light radiation angle; and (2) illuminating a wider area.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A light-emitting-diode (LED) lamp structure, comprising:
a lamp holder having a top opening;
an LED module being mounted to the top opening of the lamp holder, and including at least one LED chip and a circuit board; and
a lampshade being assembled to a top of the lamp holder to enclose the LED module therein, and having an inner wall surface coated with at least one half-mirror layer.

2. The LED lamp structure as claimed in claim 1, further comprising a plurality of radiating fins provided between the LED module and the lamp holder.

3. The LED lamp structure as claimed in claim 1, wherein the half-mirror layer is selected from the group consisting of a silver coating, an aluminum coating, and any other reflective coatings.

4. The LED lamp structure as claimed in claim 1, wherein the half-mirror layer is coated on part of the inner wall surface of the lampshade.

5. The LED lamp structure as claimed in claim 1, wherein the half-mirror layer is coated on the whole inner wall surface of the lampshade.

6. A method of increasing light radiation angle of LED lamp structure, comprising the following steps:
providing a lamp holder and mounting an LED module on the lamp holder for emitting light;
providing a lampshade and coating a half-mirror layer on an inner wall surface of the lampshade; and
assembling the lampshade to a top of the lamp holder to enclose the LED module therein, so that part of the light emitted from the LED module onto the half-mirror layer of the lampshade passes through the lampshade while other part of the light is reflected by the half-mirror layer.

7. The method as claimed in claim 6, wherein the half-mirror layer is coated on part of the inner wall surface of the lampshade.

8. The method as claimed in claim 6, wherein the half-mirror layer is coated on the whole inner wall surface of the lampshade.

9. The method as claimed in claim 6, wherein the half-mirror layer is selected from the group consisting of a silver coating, an aluminum coating, and any other reflective coatings.

10. The method as claimed in claim 6, wherein the light emitted from the LED module and reflected by the half-mirror layer is projected toward two lateral sides and a rear side of the lamp holder.
